(19) United States
(12) Patent Application Publication
(10) Pub. No.: US 2011/0121372 A1
(43) Pub. Date: May 26, 2011

(54) EDRAM Architecture

(75) Inventors: Wootag Kang, San Diego, CA (US); Zhongze Wang, San Diego, CA (US)

(73) Assignee: QUALCOMM INCORPORATED, San Diego, CA (US)

(21) Appl. No.: 12/624,509

(22) Filed: Nov. 24, 2009

(51) Int. Cl. H01L 27/108; H01L 21/8242

(52) U.S. Cl. 257/296; 438/396; 438/239; 257/E27.097; 257/E21.646

(57) ABSTRACT

A process for manufacturing an eDRAM device comprises fabricating semiconductor features on a semiconductor substrate, the semiconductor substrate including a DRAM area and logic area. The process also includes fabricating a first conductive layer in the DRAM area and in the logic area, the first conductive layer in communication with a first group of the semiconductor features. After fabricating the first conductive layer, a storage component is fabricated in communication with a second group of the semiconductor features within the DRAM area.

### TECHNICAL FIELD

The present disclosure generally relates to embedded Dynamic Random Access Memory (eDRAM). More specifically, the present disclosure relates to improved eDRAM devices and processes for fabricating improved eDRAM devices.

### BACKGROUND

Dynamic Random Access Memory (DRAM) is a type of Random Access Memory (RAM) that stores data bits in capacitors in an integrated circuit. It is generally implemented on a package separate from the package of its accompanying processor. By comparison, cache memory within a Central Processing Unit (CPU) is conventionally implemented using Static Random Access Memory (SRAM).

However, recent advances have brought embedded DRAM (eDRAM) to market. Embedded DRAM is usually integrated on the same die or in the same package as its accompanying processor. Advantages of some eDRAM devices include higher operation speeds than external DRAM and higher bit storage device density than is available in SRAM.

FIG. 1 is an example of a prior art processor device 100, which has a memory portion 101 and a logic portion 102. The memory portion 101 is an eDRAM portion that includes many capacitors used as storage devices. For ease of illustration, only one such storage device, capacitor 103, is shown. The logic portion 102 includes many logic circuits, which are also not shown for ease of illustration. On a substrate 104 are gates 110a, 110b, 110c and contacts 111a, 111b, 111c. The processor 100 includes two metal layers, M1 106 and M2 105. The M2 metal layer 105 is coupled to the M1 metal layer 106 through vias 113a, 113b. The M1 metal layer 106 is coupled to the contacts 111b, 111c through the contacts 112a, 112b.

As shown in FIG. 1, the M1 metal layer 106 is fabricated to be above the storage device 103. (As used herein, relational terms, such as “above” and below” are used with respect to the substrate 104, such that, e.g., the gates 110a, 110b, 110c are below the M1 metal layer 106, and the M1 metal layer 106 is above storage device 103). In some prior art devices, the distance from the M1 metal layer 106 to the substrate 104 is on the order of ten-thousand Angstroms. For very high density eDRAM devices, the space between the M1 metal layer 106 and the gates 110,a, 110b, 110c is so large that M1-to-gate parasitic capacitance is high enough to result in noticeable speed degradation of the processor 100. The parasitic capacitance further increases as the space between the structures 120 and 130 decreases due to scaling. Thus, the tall contact 113a, 112a, 111b becomes more problematic as the technology continues to scale.

### BRIEF SUMMARY

Various embodiments of the present invention include improved eDRAM devices and techniques to fabricate improved eDRAM devices. According to one embodiment, a process for manufacturing an eDRAM device includes fabricating semiconductor features on a semiconductor substrate, the semiconductor substrate including a DRAM area and logic area. The process also includes fabricating a first conductive layer in the DRAM area and in the logic area, the first conductive layer in communication with a first group of the semiconductor features. After fabricating the first conductive layer a storage component is fabricated in communication with a second group of the semiconductor features within the DRAM area.

In another embodiment, an integrated circuit includes a DRAM portion and a logic portion. Semiconductor structures are fabricated upon a substrate within the DRAM portion and the logic portion. A first conductive layer is disposed above the semiconductor structures in the DRAM portion and the logic portion. A storage device is disposed above at least some of the semiconductor structures in the DRAM portion. The first conductive layer is not located above the storage device.

In yet another embodiment, an integrated circuit includes a DRAM portion and a logic portion, as well as means for contacting gates within the DRAM portion and the logic portion. The contact means is fabricated upon a substrate. The integrated circuit also has a first conductive layer disposed above the contact means in the DRAM portion and the logic portion, and means for storing data disposed above at least some of the contact means in the DRAM portion. The first conductive layer is not located above the data storage means.

The foregoing has outlined rather broadly the features and technical advantages of the present invention in order that the detailed description that follows may be better understood. Additional features and advantages will be described hereinafter which form the subject of the claims of the invention. It should be appreciated by those skilled in the art that the conception and specific embodiments disclosed may be readily utilized as a basis for modifying or designing other structures for carrying out the same purposes of the present invention. It should also be realized by those skilled in the art that such equivalent constructions do not depart from the technology of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following description taken in conjunction with the accompanying drawings.

FIG. 1 is an illustration of an example prior art processor device.

FIG. 2 shows an exemplary wireless communication system 200 in which an embodiment of the disclosure may be advantageously employed.

FIG. 3 is a cut-away view of an exemplary processor adapted according to one embodiment of the invention.

FIGS. 4-10 illustrate an example process flow for fabricating the processor of FIG. 3 according to one embodiment of the invention.

### DETAILED DESCRIPTION

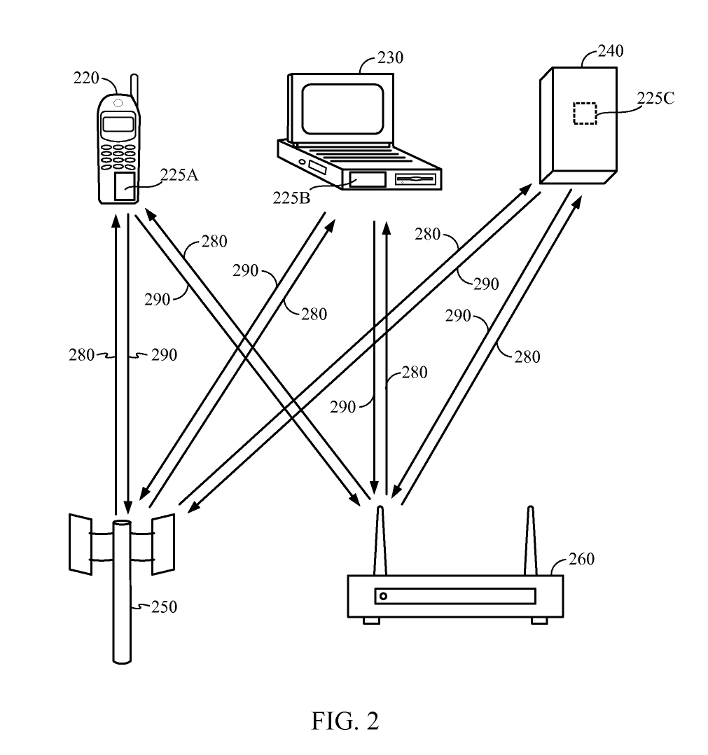

FIG. 2 shows an exemplary wireless communication system 200 in which an embodiment of the disclosure may be advantageously employed. For purposes of illustration, FIG. 2 shows three remote units 220, 230, and 240 and two base stations 250 and 260. It will be recognized that wireless communication systems may have many more remote units and base stations. Remote units 220, 230, and 240 include improved eDRAM components 225A, 225B, and 225C, respectively, which include embodiments of the invention as discussed further below. FIG. 2 shows forward link signals 280 from the base stations 250 and 260 and the remote units 220, 230, and 240 and reverse link signals 290 from the remote units 220, 230, and 240 to base stations 250 and 260.

In FIG. 2, remote unit 220 is shown as a mobile telephone, remote unit 230 is shown as a portable computer, and remote unit 240 is shown as a computer in a wireless local loop system. For example, the remote units may be mobile phones, hand-held personal communication systems (PCS) units, portable data units such as personal data assistants, GPS enabled devices, navigation devices, set top boxes, media players, such as music players, video players, game consoles, and entertainment units, fixed location data units such as meter reading equipment, or any other device that stores or retrieves data or computer instructions, or any combination thereof. Although FIG. 2 illustrates remote units according to the teachings of the disclosure, the disclosure is not limited to these exemplary illustrated units. Various embodiments may be suitably employed in any device which includes eDRAM.

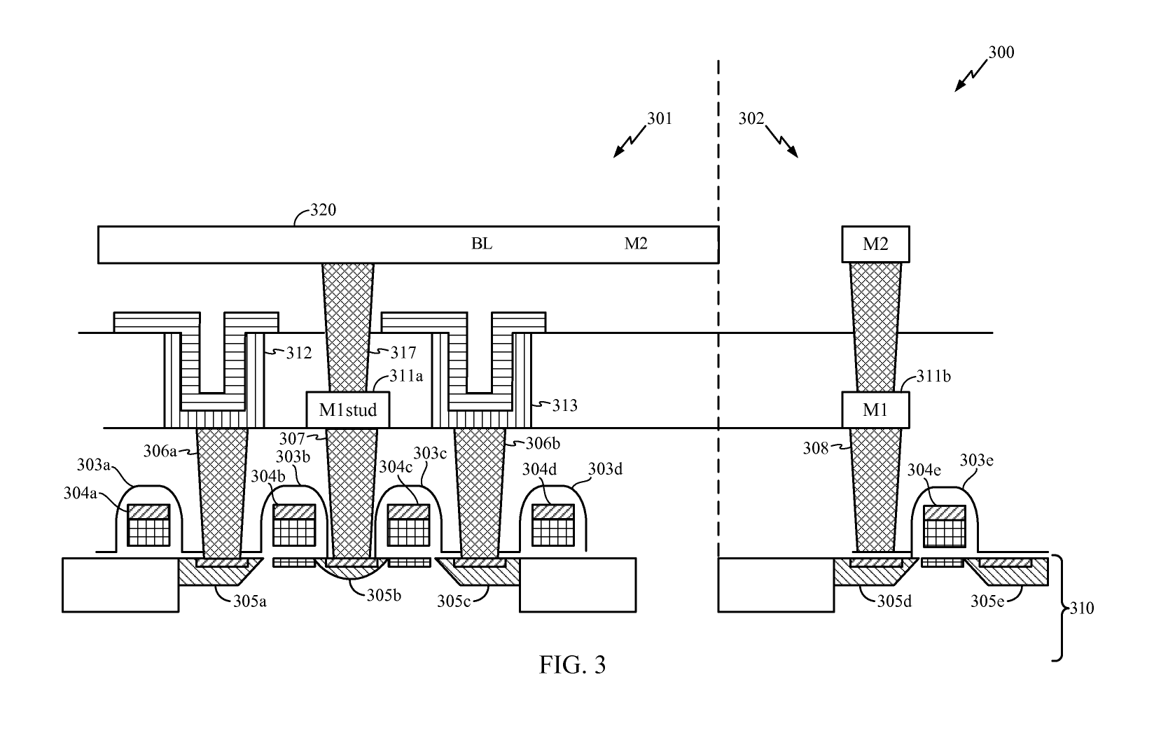

FIG. 3 is a cut-away view of an exemplary processor 300 adapted according to one embodiment of the invention. In its various embodiments, the processor 300 can be any type of processor, such as an Application Specific Integrated Circuit (ASIC), a Digital Signal Processor (DSP), a general purpose processor, and the like. The processor 300 includes the DRAM portion 301 and the logic portion 302 on the same die, where the logic portion 302 includes the logic circuitry, and the DRAM portion 301 includes on-die information storage. The DRAM portion 301 is in communication with the logic portion 302 so that the logic portion 302 can read to and write from the DRAM portion 301.

The processor 300 includes a variety of semiconductor structures disposed on the substrate 310. The semiconductor structures include word lines 303a, 303b, 303c, 303d, 303e, gates 304a, 304b, 304c, 304d, 304e, gate contacts 305a, 305b, 305c, 305d, 305e, storage node contacts 306a, 306b, a bitline contact 307, and a logic contact 308. The bitline contact 307 is part of a two-step contact that also includes a metal 1 (M1) stud 311a and another bitline contact 317, both of which are described in more detail below.

The M1 stud 311a is one part of the M1 conductive layer, as is the M1 portion 311b. The M1 conductive layer acts as the interconnect line for processor 300. In the embodiment of FIG. 3, the M1 layer is fabricated before storage devices 312 and 313 are fabricated, and the M1 layer is not placed above storage devices 312 and 313.

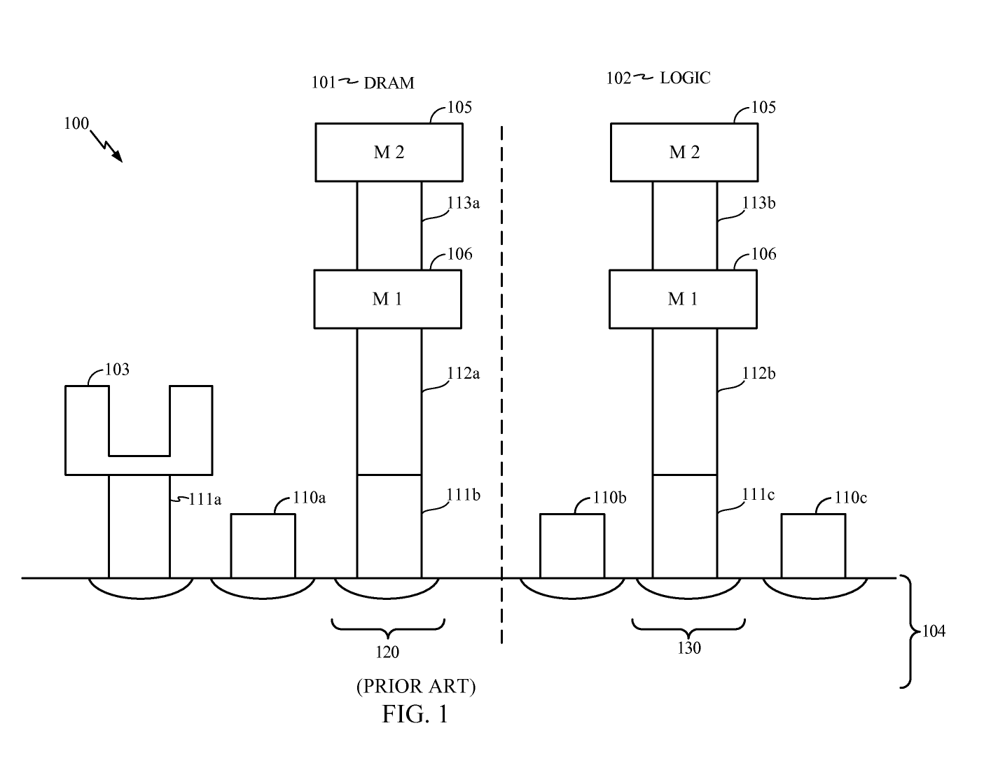

The embodiment of FIG. 3 stands in contrast to the prior art embodiment of FIG. 1, which places the M1 layer 106 above the storage device 103. Whereas the distance from the M1 layer 106 of FIG. 1 to the substrate 104 may be in the range of ten-thousand Angstroms, the M1 layer of FIG. 3 can be in the range of three-thousand Angstroms from the substrate 310 (though various embodiments of the invention are not limited to any particular distance between the M1 layer and the substrate). The embodiment of FIG. 3 includes less parasitic capacitance between the M1 layer and the gates 304a, 304b, 304c, 304d, 304e and between and among the various M1 portions (e.g., M1 portion 311a, 311b, and other M1 portions not shown) than does the embodiment of FIG. 1, because of the shorter distance from the M1 layer to the substrate 310.

The processor 300 includes storage components 312 and 313, which in this example, are metal-insulator-metal (MIM) capacitors. The storage devices 312 and 313 are in communication with the storage node contacts 306a, 306b, and the M1 stud 311a is in contact with the bitline contact 307. In this example, the M1 stud 311a and the storage devices 312 and 313 are fabricated directly above the contacts 306a, 306b, and 307, and the M1 stud 311a and the storage devices 312 and 313 are fabricated at substantially the same level.

The processor 300 employs a metal 2 (M2) conductive layer 320 as a bitline in this example. The M2 layer 320 is in communication with the contact 305b through a bitline contact 317. In another embodiment, the M1 conductive layer operates as the bitline.

In many embodiments, the bitline contact 317 (as well as the other contacts 306a, 306b, 307, and 308) is constructed as a via. The embodiment of FIG. 3 uses a two-step contact between the M2 metal layer and the substrate, which has one fewer step than do the three-step contacts used by the embodiment of FIG. 1 between the M2 metal layer 105 and the substrate. Accordingly, the embodiment of FIG. 3 can increase efficiency by using one fewer via mask.

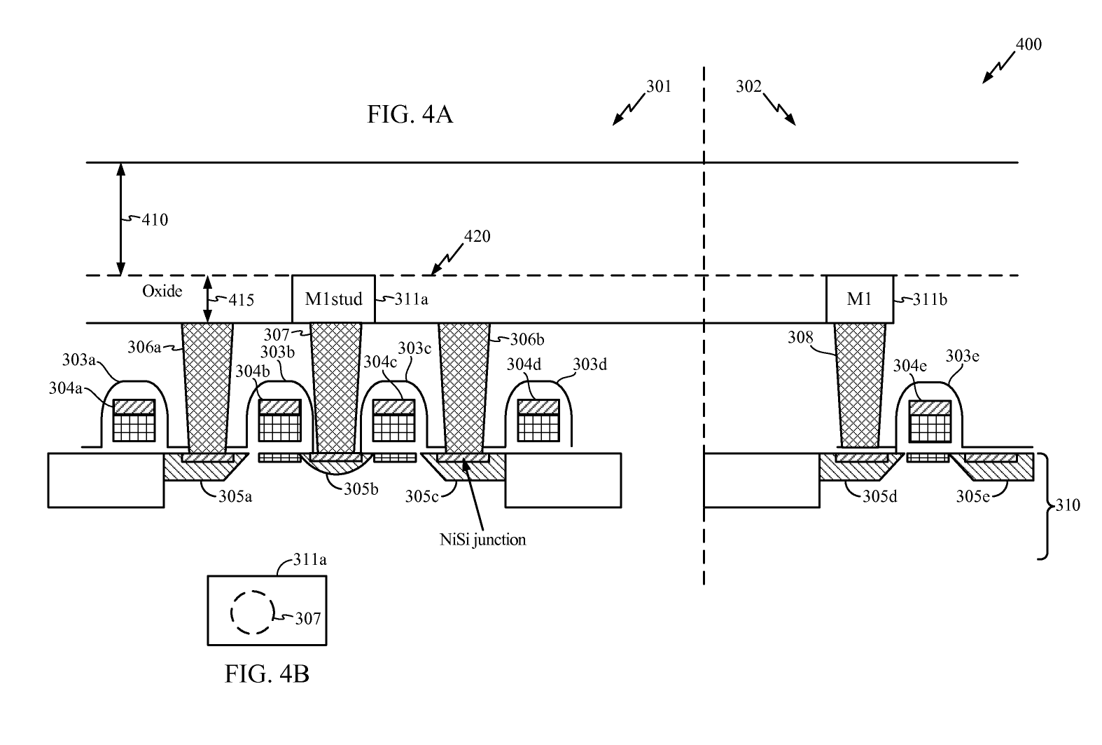

FIGS. 4-10 illustrate an example process flow for fabricating the processor 300 according to one embodiment of the invention. FIG. 4A shows a process 400, which includes Chemical Mechanical Polishing (CMP) and oxide deposition. After the M1 layer is deposited and after an M1 pattern lithograph/oxide etch, it undergoes CMP for purposes of planarization. After CMP, the M1 layer and an oxide layer 415 conform to a plane 420. The processor 300 employs a portion of the M1 layer for the stud 311a, and a top-down view of the M1 stud 311a and bitline contact 307 is shown in FIG. 4B. Oxide deposition is then performed to create the oxide layer 410.

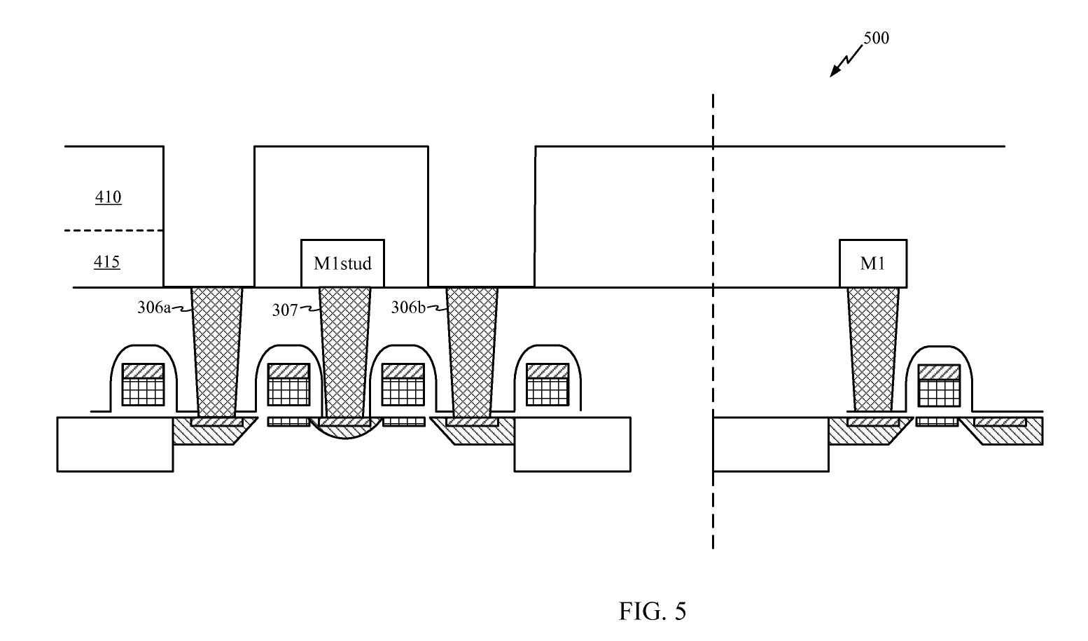

FIG. 5 shows the process 500. The process 500 includes an oxide etch in the oxide layers 410 and 415 to create recesses in which the storage devices 312 and 313 will be formed. The oxide etching removes the oxide down to the contacts 306a, 306b, and bitline contact 307.

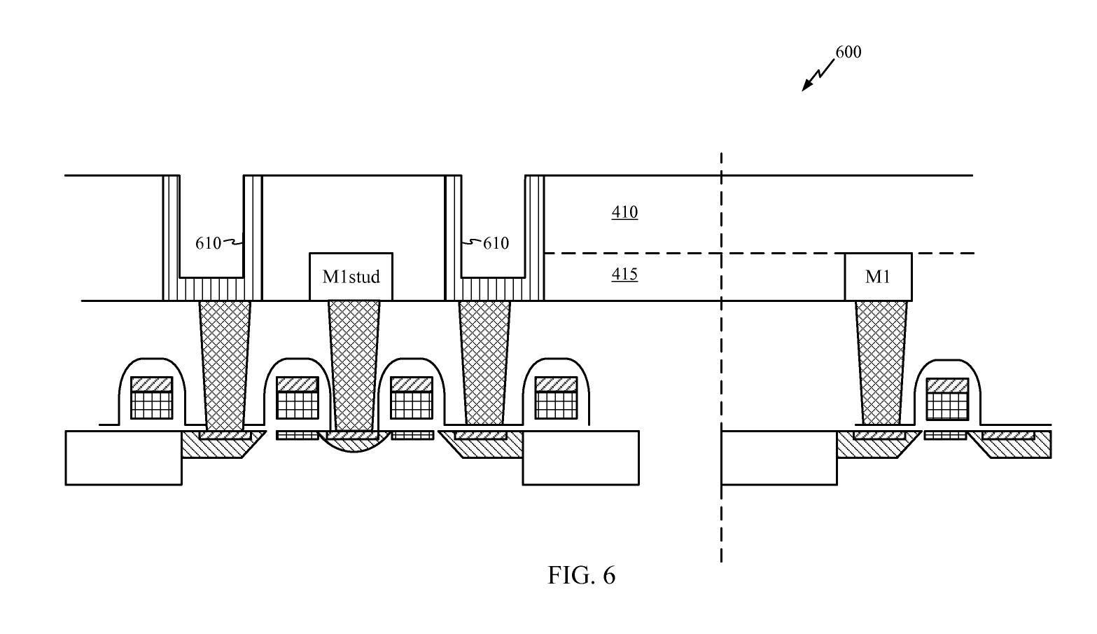

FIG. 6 shows the process 600. The process 600 includes deposition of a conductive material 610, e.g., a metal, for the storage devices 312 and 313. After the conductive material 610 is deposited, another CMP process is performed to planarize the conductive material 610 at the top of the oxide layer 410.

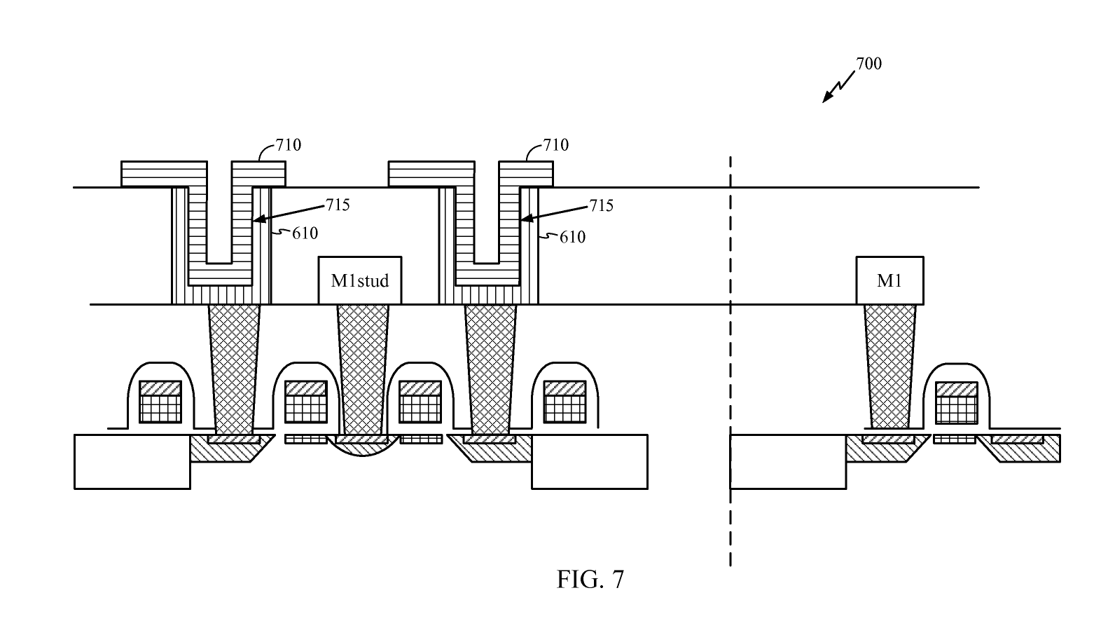

FIG. 7 shows the process 700. The process 700 includes depositing an insulator 715, e.g., a high K oxide, upon the conductive material 610. Then, process 700 deposits a conductive plate 710, e.g., a metal, on the insulator 715. The conductive plate 710 is etched after patterning by lithograph.

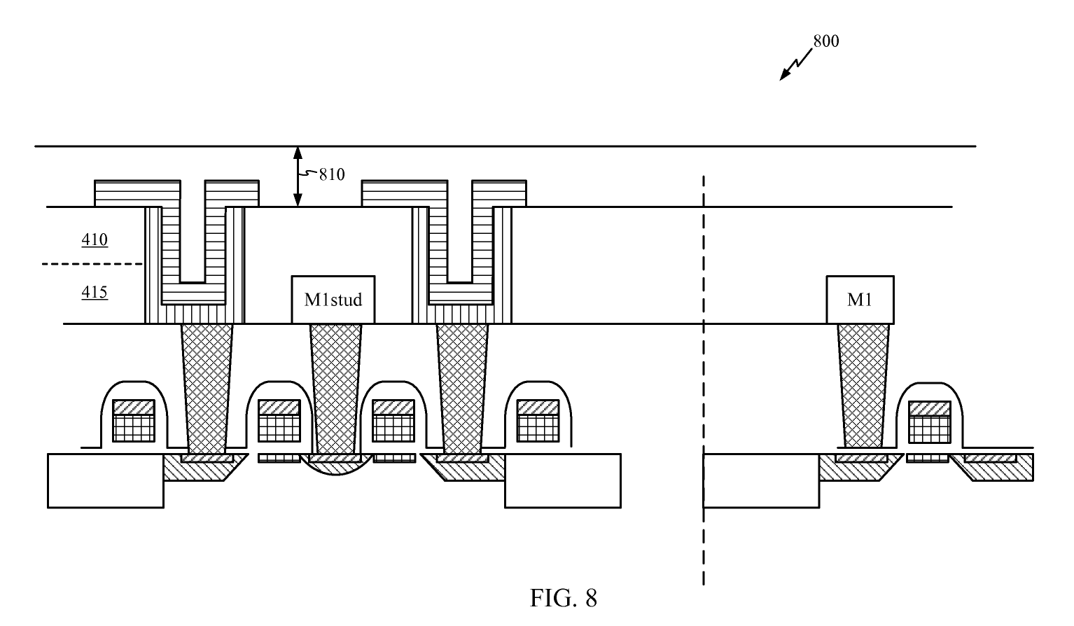

FIG. 8 shows the process 800. The process 800 includes depositing an oxide layer 810 on the storage devices 312 and 313 and on the oxide layer 410.

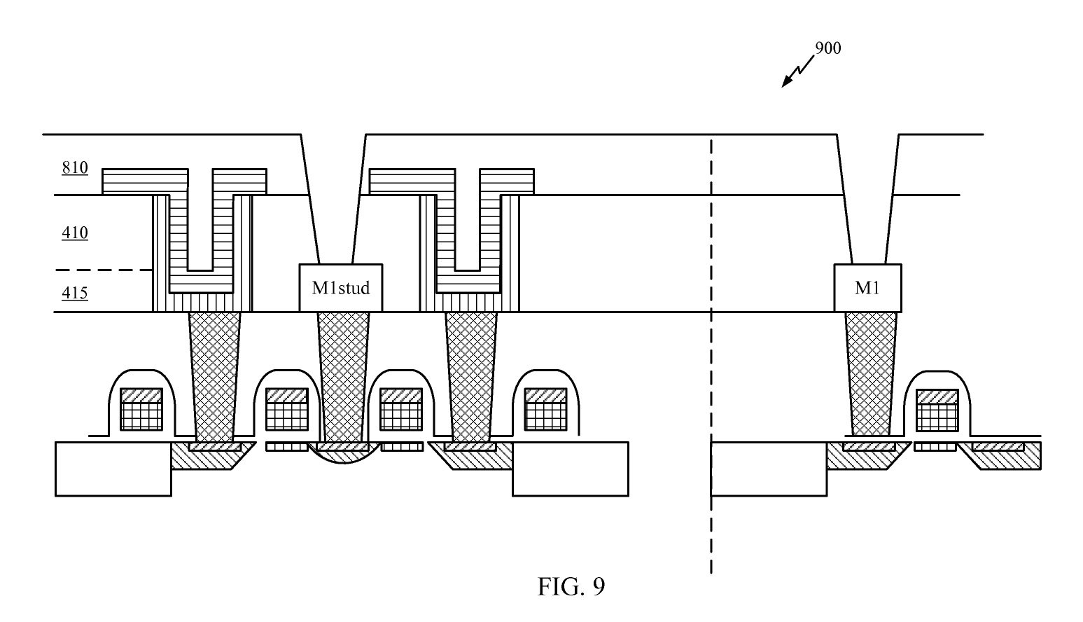

FIG. 9 shows the process 900, which includes etching oxide layers 810 and 410 down to the M1 layer, including the M1 stud 311a and the M1 portion 311b. The etch is in preparation of enabling communication with the M1 layer, by for example, vias.

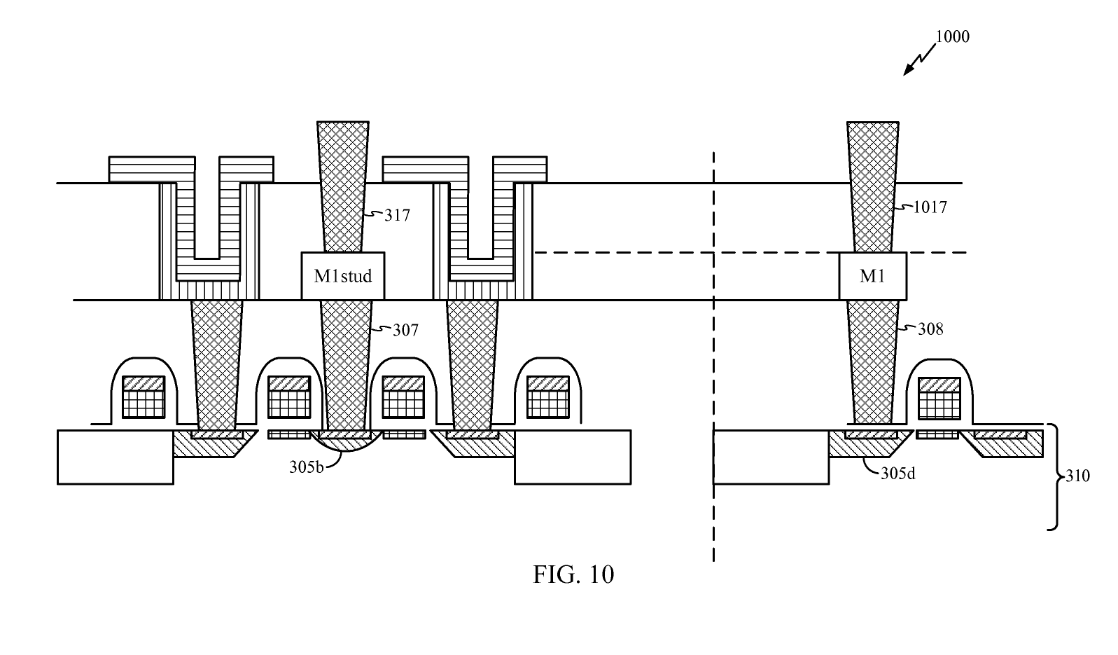

FIG. 10 shows the process 1000, which includes fabricating the contacts 317 and 1017 as vias in the etched recesses from process 900. The contacts 317 and 1017 provide a communication path from the M2 conductive layer to the contacts 305b, 305d in the substrate 310. The contact area of the M1 contact stud 311a is larger than the contact areas of the bitline contacts 307 and 317 (as shown in FIG. 4A), thereby providing for convenient alignment during processes 400, 900, and 1000. In another embodiment, the M1 contact stud 311a is not fabricated. In this embodiment, the bitline contact 317 is directly on the bitline contact 307. In either embodiment, the M2 conductive layer is then deposited, as shown in FIG. 3.

While FIGS. 4-10 show one example method for fabricating a processor according to one embodiment, other embodiments may use other methods. Specifically, other embodiments may add, omit, rearrange, or modify one or more of the processes 400-1000 while fabricating the M1 conductive layer before fabricating one or more storage components. Additionally, various embodiments include implementing the processor in a system such as a computer, phone, game console, or the like.

Various embodiments include advantages over prior art embodiments. For instance, the embodiment of FIG. 3 includes less parasitic capacitance, and thus greater speed, than the embodiment of FIG. 1 (assuming the density of contacts is similar in the embodiments of FIG. 1 and FIG. 3). Furthermore, the M1 stud 311a of FIG. 3 can be somewhat wider than the studs 107a, 107b of FIG. 1, thereby increasing yield by ameliorating alignment issues. Additionally, the embodiment of FIG. 3 replaces the three-step contacts of FIG. 1 with two-step contacts, thereby eliminating one via mask.

Although specific circuitry has been set forth, it will be appreciated by those skilled in the art that not all of the disclosed circuitry is required to practice the invention. Moreover, certain well known circuits have not been described, to maintain focus on the invention.

Although the present invention and its advantages have been described in detail, it should be understood that various changes, substitutions and alterations can be made herein without departing from the technology of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A process for manufacturing an embedded dynamic random access (eDRAM) device, the process comprising:
fabricating semiconductor features on a semiconductor substrate, the semiconductor substrate including an eDRAM area and logic area;
fabricating a first conductive layer in the logic area, the first conductive layer in communication with a first group of the semiconductor features; and
after fabricating the first conductive layer, fabricating a storage component in communication with a second group of the semiconductor features within the eDRAM area.

2. The process for manufacturing an eDRAM device of claim 1, further comprising:
fabricating a second conductive layer after fabricating the storage component, the second conductive layer communicating with the first conductive layer.

3. The process for manufacturing an eDRAM device of claim 2, wherein the semiconductor features comprise a plurality of transistor components, and wherein the second conductive layer comprises a bit line.

4. The process for manufacturing an eDRAM device of claim 2 further comprising:
fabricating a via above the first conductive layer before fabricating the second conductive layer, the via providing communication between the first conductive layer and the second conductive layer.

5. The process for manufacturing an eDRAM device of claim 1 wherein fabricating the semiconductor features comprises:
fabricating first contacts in communication with gates on the semiconductor substrate; and
fabricating second contacts in communication with the first contacts.

6. The process for manufacturing an eDRAM device of claim 5, wherein fabricating the first conductive layer comprises:
fabricating a stud on a first one of the second contacts to be in communication with a first one of the first contacts.

7. The process for manufacturing an eDRAM device of claim 1, wherein fabricating the storage component comprises:
fabricating a capacitor in an oxide layer above the semiconductor features.

8. The process for manufacturing an eDRAM device of claim 1 further comprising:
incorporating the eDRAM device into a system selected from a group consisting of a music player, a video player, an entertainment unit, a navigation device, a communications device, a personal digital assistant (PDA), a fixed location data unit, a game console, and a computer.

9. A process for manufacturing an eDRAM device, the process comprising the steps of:
fabricating semiconductor features on a semiconductor substrate, the semiconductor substrate including a DRAM area and logic area;
fabricating a first conductive layer in the DRAM area and in the logic area, the first conductive layer in communication with a first group of the semiconductor features; and
after fabricating the first conductive layer, fabricating a storage component in communication with a second group of the semiconductor features within the DRAM area.

10. The process for manufacturing an eDRAM device of claim 9 further comprising the step of:
incorporating the eDRAM device into a system selected from a group consisting of a music player, a video player, an entertainment unit, a navigation device, a communications device, a personal digital assistant (PDA), a fixed location data unit, a game console, and a computer.

11. An integrated circuit comprising:
an embedded dynamic random access (DRAM) portion and a logic portion;
a plurality of semiconductor structures within the eDRAM portion and the logic portion fabricated upon a semiconductor substrate;
a first conductive layer disposed above the plurality of semiconductor structures in the logic portion; and
a storage device disposed at substantially a same level as the first conductive layer, the storage device communicating with at least some of the semiconductor structures in the eDRAM portion.

12. The integrated circuit of claim 11 further comprising:
a second conductive layer disposed above the storage device and the first conductive layer, the second conductive layer in communication with the first conductive layer.

13. The integrated circuit of claim 12 wherein the second conductive layer comprises a bitline.

14. The integrated circuit of claim 11 incorporated into a device selected from a group consisting of a music player, a video player, an entertainment unit, a navigation device, a communications device, a personal digital assistant (PDA), a fixed location data unit, a game console, and a computer.

15. The integrated circuit of claim 11, in which the integrated circuit is integrated into a semiconductor die.

16. The integrated circuit of claim 11 wherein the first conductive layer comprises at least one stud in communication with at least one of the semiconductor structures.

17. The integrated circuit of claim 16, wherein the at least one stud is disposed between a first bitline contact and a second bitline contact.

18. The integrated circuit of claim 17, wherein the at least one stud has a cross-section larger than a top area of the first bitline contact and larger than a bottom area of the second bitline contact.

19. The integrated circuit of claim 11 wherein the storage device comprises a capacitor.

20. The integrated circuit of claim 11 further comprising an additional storage device and a stud including a portion of the first conductive layer disposed between first and second bitline contacts, the stud disposed between the storage device and the additional storage device.

21. An integrated circuit comprising:
an embedded dynamic random access (eDRAM) portion and a logic portion;
means for contacting a plurality of gates within the eDRAM portion and the logic portion, the contacting means being fabricated upon a semiconductor substrate;
a first conductive layer disposed on the contacting means in the eDRAM portion and the logic portion; and
means for storing data disposed above at least some of the contacting means in the eDRAM portion, the first conductive layer disposed substantially on the same level as the data storage means.

22. The integrated circuit of claim 21 incorporated into a device selected from a group consisting of a music player, a video player, an entertainment unit, a navigation device, a communications device, a personal digital assistant (PDA), a fixed location data unit, a game console, and a computer.

23. The integrated circuit of claim 21, in which the integrated circuit is integrated into a semiconductor die.

24. The integrated circuit of claim 21 wherein the data storage means comprise a plurality of capacitors.

25. The integrated circuit of claim 21 wherein the contacting means includes a plurality of vias coupling the data storage means to the plurality of gates.
